(19) United States
(12) Patent Application Publication
(10) Pub. No.: US 2008/0143319 A1
(43) Pub. Date: Jun. 19, 2008

(54) Power Distributor with Built-In Power Sensor

(75) Inventor: Eric Breakenridge, Clackmannanshire (GB)

Correspondence Address: AGILENT TECHNOLOGIES INC., INTELLECTUAL PROPERTY ADMINISTRATION,LEGAL DEPT., MS BLDG. E P.O. BOX 7599, LOVELAND, CO, 80537, US

(73) Assignee: AGILENT TECHNOLOGIES, INC., Loveland, CO (US)

(21) Appl. No.: 11/554,409

(22) Filed: Oct. 30, 2006

(51) Int. Cl. G01R 27/02

(52) U.S. Cl. 324/95

(57) ABSTRACT

A power-sensor module comprises a housing enclosing the power-sensor module. An input port of the housing brings an input signal into the housing. A power distributor, is within the housing. The power distributor has a first arm transmitting a first portion of the input signal and a second arm transmitting a second portion of the input signal. A first resistor is in the first arm and a second resistor in the second arm of the power distributor. An output port of the housing outputs from the housing the first portion of the input signal. A first thermal-based power detector detects heat generated by the second resistor caused by the second portion of the input signal and outputs a first power measurement signal based on the heat detected.

### BACKGROUND OF THE INVENTION

FIG. 1 shows an example of a prior-art apparatus 100 for taking a power measurement together with another RF measurement of an RF signal from a device under test (DUT) 101. The input port of an Agilent 11667A DC to 18 GHz Power Splitter 103 is connected to the DUT 101. The power is divided between the two output ports of the power splitter.

One of the output ports is connected through an Agilent 8481A Power Sensor 105 and to an Agilent E4418B Power Meter 107. Agilent is a trademark of Agilent Technologies, Inc. of Santa Clara, Calif., USA.

The Agilent 8481A is a thermocouple-based sensor. Thermocouple power sensors are thermal-based power sensors. Thermal-based power sensors are true “averaging detectors” and in addition to thermocouple power sensors also include bolometer (thermistor or barretter) power sensors. They convert an unknown RF power to heat and detect that heat transfer. In other words they measure heat generated by the RF energy.

The other output port is connected to another device such as a spectrum analyzer or frequency detector 109.

One problem with this prior-art method is that the separate components need to be specified and calibrated separately. Also, the power measuring sensitivity of the power sensor 105 and power meter 107 is not optimized.

It would be desirable to combine a power sensor with a power distributor, such as a power splitter or power divider, so as to provide more accurate measurements with less calibration, as well as greater sensitivity of power measurement.

### SUMMARY OF THE INVENTION

The present invention provides a single device which incorporates a power sensor within an arm of a power distributor.

A power-sensor module comprises a housing enclosing the power-sensor module. An input port of the housing brings an input signal into the housing. A power distributor, for example a power divider or power splitter, is within the housing. The power distributor has a first arm transmitting a first portion of the input signal and a second arm transmitting a second portion of the input signal. A first resistor is in the first arm and a second resistor in the second arm of the power distributor. An output port of the housing outputs from the housing the first portion of the input signal. A first thermal-based power detector detects heat generated by the second resistor caused by the second portion of the input signal and outputs a first power measurement signal based on the heat detected. An analog-to-digital converter within the housing converts the first power measurement signal to a digital signal. The digital signal is output from a digital output port of the housing for outputting the digital signal or transmitted by a transmitter. The input signal, the first portion of the input signal and the second portion of the input signal can be RF signals.

### BRIEF DESCRIPTION OF THE DRAWINGS

Further preferred features of the invention will now be described for the sake of example only with reference to the following figures, in which:

FIG. 1 shows an example of a prior-art apparatus for taking a power measurement together with another RF measurement of an RF signal from a device under test (DUT).

FIG. 2 shows a power-sensor module of the present invention enclosed within a housing and connected into a test or measurement system.

FIG. 3 shows internal circuitry of the power-splitting power sensor of FIG. 2.

FIG. 4 shows internal circuitry of the power-splitting power sensor of FIG. 2 modified to include an additional second power sensor in the second arm of the power distributor.

FIG. 5 shows internal circuitry of the power-splitting power sensor of FIG. 2 modified to have a single 100 ohm power dissipating resistor used with the first power sensor.

FIG. 6 shows a simplified schematic of the internal circuitry of a power meter portion of the power-sensor module.

### DETAILED DESCRIPTION

FIG. 2 shows a power-sensor module 201 of the present invention enclosed within a housing 202 and connected into a test or measurement system 200. The housing 202 of the power-sensor module 201 has an input port 205. The input port 205 of the power-sensor module 201 receives an input signal 206 from a DUT 203 via a transmission media 207. In one embodiment the input signal 206 has a frequency in the RF range. The RF frequency range is considered to cover frequencies from approximately 150 kHz up to the IR range. In other embodiments the frequency can be in the microwave frequency range of 1 GHz and higher or the frequency can be in the optical range. The transmission media 207 can be cable, waveguide, or other media.

A portion of the power of the input signal 206 received by the input port 205 passes through the power-sensor module 201 and is output at an output port 209 of the power-sensor module 201 as a signal 210. The signal 210 is generally the same as the input signal 206 (for example it has the same frequency characteristics) but has attenuated power. The output port 209 sends the signal 210, via a transmission media 211, to a measurement device 213, such as a spectrum analyzer, frequency meter or other RF or optical frequency device for measuring a parameter of the signal. The power measurement device 213 can be an Agilent PSA Series E4448A Spectrum Analyzer, for example. The transmission media 211 can be cable, waveguide, or other media.

A power measurement signal 217 is output from an output port 215 and is transmitted to the measurement device 213 via a transmission media 219. The power measurement signal 217 contains information indicative of the power of the input signal 206 received by the input port 205. The power measurement signal 217 can be formatted and output from the power sensor module 201 using protocols such as USB, Ethernet, LAN, RS232, IEEE 1394, GPIB, HPIB, VXI, PCI Express, PCI, PXI, LXI, PCMCIA or others as known in the art.

Alternatively, the output port 215 can be a transmitter and the signal 217 can be transmitted through the air to a receiver at the measurement device 213. In this case the wireless format can be WiFi, WUSB or IrDA.

In the case where the measurement device 213 is a Spectrum Analyzer, the power measurement signal 217 can serve as an absolute reference for power measurement.

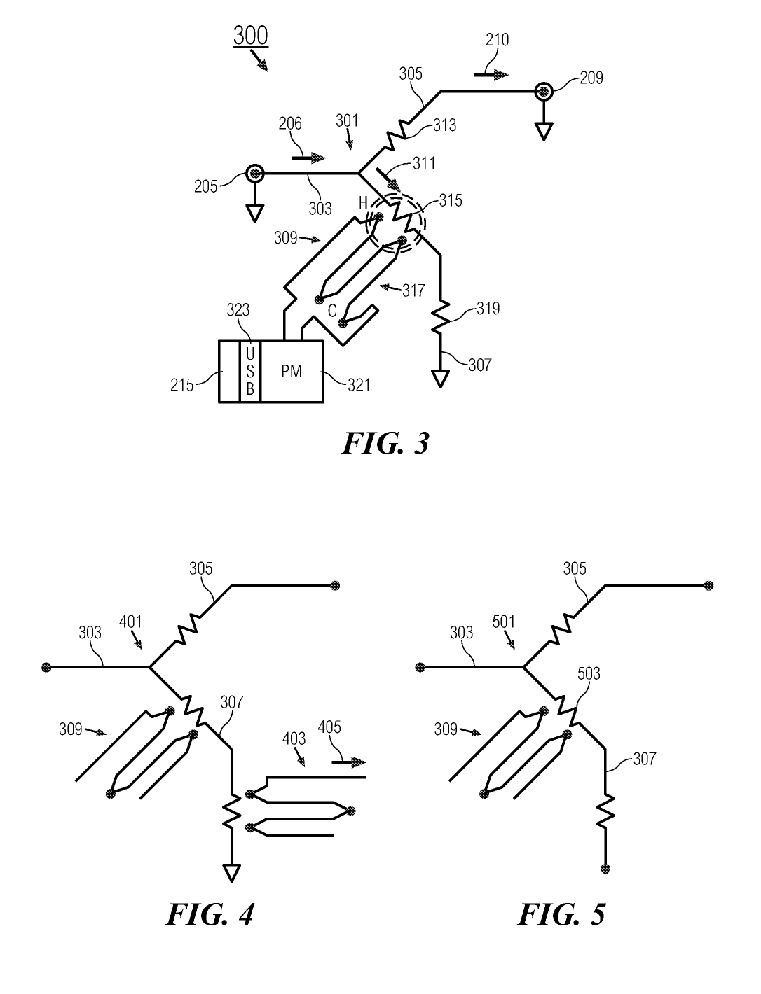

FIG. 3 shows the internal circuitry 300 of the power-sensor module 201. The circuitry 300 is comprised of a power distributor 301 having an input arm 303 which receives the input signal 206 through the input port 205. The input port 205 brings the input signal 206 into the housing 202. The power distributor 301 divides the input signal 206 into a first signal portion 210 of the input signal 206 and a second signal portion 311 of the input signal 206. The power distributor 301 has a first arm 305 transmitting the first signal portion 210 and a second arm 307 transmitting the second signal portion 311.

The first arm 305 outputs the first signal portion 210 from the output port 209 of the housing 202.

The power distributor 301 shown in FIG. 3 is a two-resistor power splitter with a first resistor 313 in the first arm 305 and a second resistor 315 in the second arm 307. In the example of a power splitter, one quarter of the signal delivered to the input port 205 is delivered to each of the arms 305, 307. Two-resistor power splitters are useful for power leveling of signal generators, among other applications. They are used to improve the effective output match of microwave sources through either a leveling loop or a ratio measurement.

Another resistor, 319 can also be in the second arm 307. Typically, in a two-resistor power splitter 301, the output port 209 is terminated in 50 ohms. For example, the output port 209 might be terminated with a transmission media 211 consisting of a 50 ohm coaxial cable and a measurement device 213 having a 50 ohm characteristic impedance. The resistors 313, 315 can also be 50 ohms. If the resistor 319 is 50 ohms as well, then an equal amount of power will pass through each of the arms 305, 307.

In another embodiment the power distributor 301 can be a three-resistor power divider having an additional resistor in the input arm 303. The three-resistor power dividers are useful for power monitoring applications, or other applications where it is necessary to divide power equally on a uniform transmission line.

A first power sensor 309 is in the second arm 307 of the power distributor 301. The first power sensor 309 receives the second signal portion 311 and produces the power measurement signal 217 which is output from the output port 215 of the housing 202.

The first power sensor 309 can be a thermal-based power detector serving as a true “averaging detector” and can be, for example, a thermocouple detector, a thermistor detector or a barretter detector. The thermal-based power detectors convert an unknown RF power to heat and detect the heat transfer. In other words they measure heat generated by the RF energy. Other types of average power measurement detectors can also be used.

The first power sensor 309 can use an RF thermocouple detector including one or more thermocouple units, forming a “thermopile” 317, and coupled on a unitary substrate. Each thermocouple unit consists of a pair of thermocouples in series, one nominally “hot” and the other nominally “cold”. In FIG. 3, the resistor 315 is serially connected in the second arm 307 and is electrically isolated from the thermopile 317. The resistor 315 is positioned adjacent to the “hot” junctions of the thermopile 317 so that it can sense the heat coming from the resistor 315 as it is heated by the power of the second signal portion 311. Thus, the thermopile 317, along with any additional processing circuitry, serves as a first thermal-based power detector for detecting heat generated by the second resistor 315 caused by the second portion 311 of the input signal 206. The signal from the thermopile 317 is used to provide the first power measurement signal 217 based on the heat detected from the resistor 315.

The thermopile 317 can just as well be associated with the resistor 319 rather than the resistor 315 to detect the heat generated by the resistor 319.

By utilizing a resistor of the power distributor 301 as part of the first power sensor 309, the calibration of the power sensor module 201 is greatly simplified and the accuracy is increased.

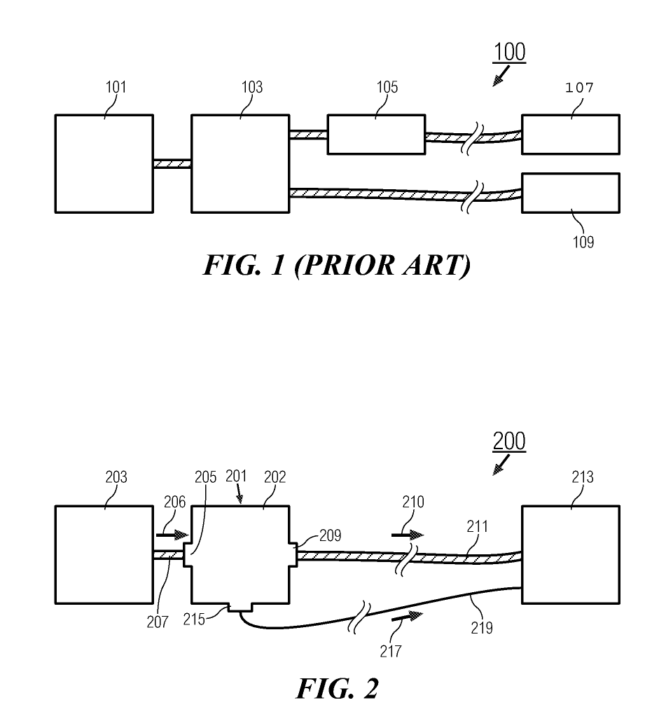

The first power sensor 309 can be calibrated similarly to a traditional power sensor, such as the power sensor 105 of FIG. 1, except that the output port 209 is terminated with a fixed 50 ohm load. Further calibration is carried out with the output port 209 terminated in an open and with a short.

FIGS. 4 and 5 illustrate embodiments of the present invention providing twice the sensitivity of the embodiment of FIG. 3.

The power distributor 401 of FIG. 4, in addition to the first power sensor 309 of FIG. 3, also has a second power sensor 403 utilizing the heat generated by the resistor 319 of the second arm 307 of the power distributor 401. The second power sensor 403 produces a second power measurement signal 405. The first and second power measurement signals 403, 405 can be added digitally or added with a series connection.

The power distributor 501 of FIG. 5 modifies the second arm 307 by using a single 100 ohm resistor 503 with the first power sensor 309 in place of the resistor 315 and resistor 319 of FIG. 3.

The resistor configurations of the power distributors 401, 501 of FIGS. 4 and 5 increase the sensitivity and accuracy of the power measurements as described by first returning to the two-resistor power splitter 301 of FIG. 3. In this example, the output port 209 is terminated in 50 ohms. For example, the output port 209 might be terminated with a transmission media 211 consisting of a 50 ohm coaxial cable and a measurement device 213 having a 50 ohm characteristic impedance. The resistors 313, 315 can also be 50 ohms. If the resistor 319 is 50 ohms as well, then an equal amount of power will pass through each of the arms 305, 307. Therefore, in the arm 307, one quarter of the power of the input signal 206 will be delivered to the resistor 315 and one quarter to the resistor 319.

In prior-art power-distributors, the resistors within the output arms are not used for power sensors such as the first power sensor 309. Thus, the power sensor measurement is made based on at most only one-quarter of the input power and potential sensitivity is lost.

In the embodiment of FIG. 4 the sensitivity and accuracy is increased by sensing the heat from both of the resistors and thereby makes use of up to one-half of the input power for power measurement.

In the embodiment of FIG. 5, up to one-half of the input power is used for power measurement by utilizing the single resistor 503 having a larger resistance (here 100 ohms) for power measurement.

Thus, the embodiments of FIGS. 4 and 5 allow twice the power of the prior art to be converted into voltage by the power sensors, which in effect gives up to twice the sensitivity.

In other embodiments combinations of different types of power sensors can be used within the power sensor module 201. For example, the second power sensor 403 can be any type of thermal-based or diode-based sensor. Also, in FIG. 5 the first power sensor 309 and resistor 315 can be replaced with a single thermal-based or diode-based sensor having an impedance of 100 ohms. Combining a diode-based sensor adds the advantage of monitoring the power envelope to obtain more information about the input signal 206.

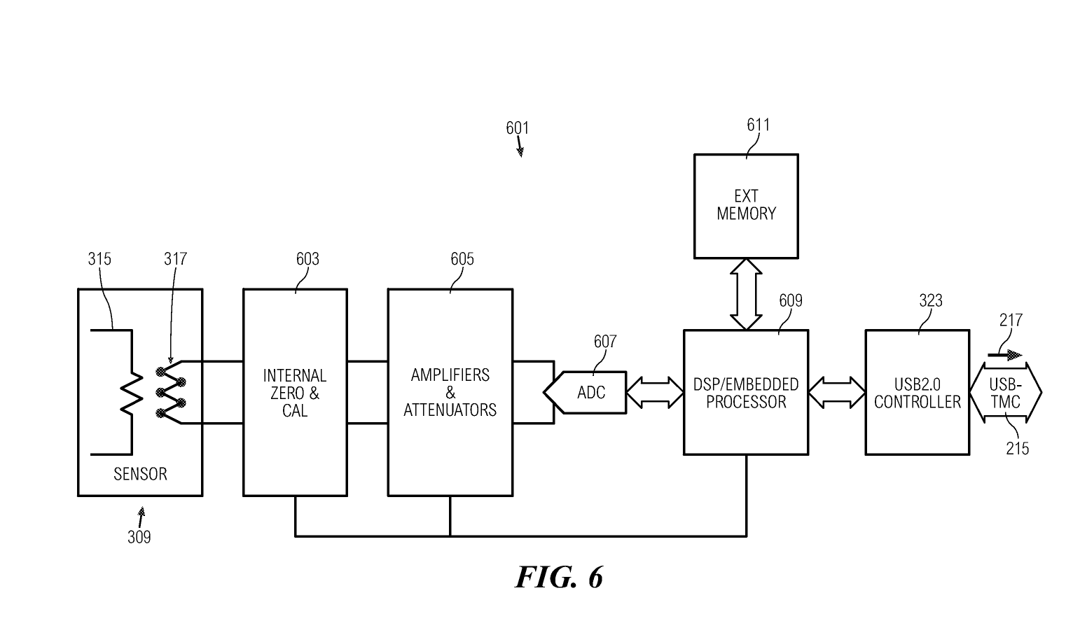

FIG. 6 shows a simplified schematic of the internal circuitry 601 of the power meter section 321 within the power-sensor module 201. A DC signal related to the heat produced by the resistor 315 and detected by the thermopile 317 is output from the first power sensor 309. An internal zero and calibration section 603 receives signal and provides output to a section of amplifiers and attenuators 605. The analog signal is digitized by an analog to digital converter 607. The digitized signal is sent to the DSP/embedded processor 609. The DSP/embedded processor 609 controls the internal zero and calibration section 603, the amplifiers and attenuators 605 and the analog to digital converter 607. The DSP/embedded processor 609 can also utilize an external memory 611. The processed signal is then converted to the USB protocol by the USB2.0 Controller 323. Controllers for other protocols can be substituted for other systems. The USB2.0 Controller 323 outputs the first power measurement signal 217 from the output port 215 which in this case is a digital output port. The power measurement signal 217 contains information indicative of the power of the input signal 206 received by the input port 205. The signal 217 can then be sent through the transmission media 219 to the measurement device 213.

Including the power meter section 321 within the power-sensor module 201 avoids the extra size, weight and cost of using external power meter such as the power meter 105 of FIG. 1.

In other embodiments the power meter section 321 is external to the power-sensor module 201 and outside of the housing 202. In general the signal 217 can be of a format typically output by RF power sensors or of a format typically output by RF power meters, as known in the art. When the signal 217 has a format typically output by RF power sensors, then the signal 217 can be output from the output port 215 and then travels through transmission media 219 to an external power meter which can be a typical power meter such as the power meter 105 of FIG. 1.

In yet another embodiment, the first arm 305 of the power distributor 301 of FIG. 3 can include other measurement devices. For example, a power sensor, which might be similar to the first power sensor 309, can be used to measure the power of the signal 210 passing through the first resistor 313 in the first arm 305.

Including power sensors in both the first arm 305 and second arm 307 of the power distributor 301 can help to determine the match of the load on the output port 209. The proportion of power delivered to the arm 305 compared to that delivered to the arm 307 is dependant upon the load presented at the output port 209. Under the ideal conditions of a perfect 50 ohm load on the port 209, the sensors on the first and second resistor 313, 315 would measure the same power. Or alternatively, for the embodiments of FIGS. 4 and 5 the sensor on the resistor of the arm 305 would measure a power half of that measured by the sensors of the arm 307. However, if the load presented to the output port 209 is less than 50 ohms then the power measured on the resistor 313 will be greater than the power measured on the resistor 315 (or greater than half the power for the embodiments of FIGS. 4 and 5). On the other hand, if the load presented to the output port 209 is greater than 50 ohms then the power measured on the resistor 313 will be less than the power measured on the resistor 315 (or less than half the power for the embodiments of FIGS. 4 and 5). Thus, this can allow for the determination of additional parameters of a device under test (DUT) at the output port 209.

In the foregoing specification, the invention has been described with reference to specific exemplary embodiments thereof. The specification and drawings are, accordingly, to be regarded in an illustrative sense rather than a restrictive sense.

1. A power-sensor module comprising:
a housing enclosing the power-sensor module;
an input port of the housing for bringing an input signal into the housing;
a power distributor within the housing, the power distributor having a first arm transmitting a first portion of the input signal and a second arm transmitting a second portion of the input signal;
a first resistor in the first arm and a second resistor in the second arm of the power distributor;
an output port of the housing for outputting from the housing the first portion of the input signal; and
a first thermal-based power detector for detecting heat generated by the second resistor caused by the second portion of the input signal and outputting a first power measurement signal based on the heat detected.

2. The power-sensor module of claim 1, wherein the power distributor is a power divider or a power splitter.

3. The power-sensor module of claim 1, wherein the first thermal-based power detector is a thermocouple detector.

4. The power-sensor module of claim 1, wherein the first thermal-based power detector is a thermistor detector.

5. The power-sensor module of claim 3, wherein the first thermal-based power detector comprises:
a thermopile having at least one pair of thermocouples in series, wherein each pair includes one “HOT” and one “COLD” junction; and
wherein the second resistor is adjacent to a “HOT” junction and electrically isolated from the thermopile.

6. The power-sensor module of claim 1, further comprising an output port of the housing for outputting the first power measurement signal.

7. The power-sensor module of claim 1, further comprising:
an analog-to-digital converter within the housing for converting the first power measurement signal to a digital signal; and
a digital output port of the housing for outputting the digital signal.

8. The power-sensor module of claim 1, further comprising:
an analog-to-digital converter within the housing for converting the first power measurement signal to a digital signal; and
a transmitter for transmitting the digital signal.

9. The power-sensor module of claim 1, further comprising a second power sensor in the second arm of the power distributor, the second power sensor receiving the second portion of the input signal and producing a second power measurement signal.

10. The power-splitting power detector of claim 1, wherein the second resistor is 50 ohms.

11. The power-sensor module of claim 1, wherein the second resistor is 100 ohms.

12. The power-sensor module of claim 7, wherein the digital output port is a USB port.

13. The power-splitting power detector of claim 1, wherein the first power measurement signal is output to a power meter.

14. The power-splitting power detector of claim 1, wherein the input signal, the first portion of the input signal and the second portion of the input signal are all RF signals.

15. The power-splitting power detector of claim 1, wherein the output port outputs the first portion through the transmission media to a frequency meter or to a spectrum analyzer.

16. The power-splitting power detector of claim 1, further comprising a thermal-based power detector for detecting heat generated by the first resistor caused by the first portion of the input signal and outputting a power measurement signal based on the heat detected.
